(19) United States
(12) Patent Application Publication
(10) Pub. No.: US 2013/0206712 A1
(43) Pub. Date: Aug. 15, 2013

(54) Solar Assembly Structure

(71) Applicants: Pedro Magalhaes, Mountain View, CA (US); Aaron Schradin, Holland, MI (US); Dong Ho Choi, Palo Alto, CA (US); Evan Green, San Jose, CA (US)

(72) Inventors: Pedro Magalhaes, Mountain View, CA (US); Aaron Schradin, Holland, MI (US); Dong Ho Choi, Palo Alto, CA (US); Evan Green, San Jose, CA (US)

(73) Assignee: SOLFOCUS, INC, San Jose, CA (US)

(21) Appl. No.: 13/587,929

(22) Filed: Aug. 17, 2012

Related U.S. Application Data
(60) Provisional application No. 61/528,743, filed on Aug. 29, 2011.

(51) Int. Cl. H01L 31/042

(52) U.S. Cl. CPC H01L 31/0424
USPC 211/41.1; 29/428

(57) ABSTRACT

A solar concentrator assembly includes a pair of rails coupled together only by one or more backpans which are mounted between the pair of rails. The rails are configured to resist a portion of a cantilever deflection along the length of the rails. The backpans seat solar concentrator arrays and are configured to provide torsional rigidity and deflection resistance in at least one direction orthogonal to the cantilever deflection.

### RELATED APPLICATIONS

This application claims priority to U.S. Provisional Patent Application No. 61/528,743 filed Aug. 29, 2011, entitled “Solar Assembly Structure,” and which is hereby incorporated by reference for all purposes.

### BACKGROUND OF THE INVENTION

In the production of solar energy, arrays of solar collectors are typically mounted onto a tracking system. The tracking system changes the angular orientation of the solar collectors, such as solar panels or arrays, so that they are directed toward the sun in order to maximize solar collection. Numerous solar arrays are mounted on one tracker, and consequently the tracker conventionally requires a substantial structural framework involving beams, trusses, and the like to support the weight of the arrays. For pedestal-mounted systems in particular, an expansive solar module atop a single pole serves a large cantilever, requiring heavy frames and materials to resist the high wind loads resulting from this type of design.

For solar concentrators, it is particularly important that the mounted arrays are accurately leveled and aligned on the solar tracker. Misalignment of the optical components in a solar concentrator can affect the efficiency of a concentrating system.

### SUMMARY OF THE INVENTION

A solar concentrator assembly includes a pair of rails coupled together only by one or more backpans which are mounted between the pair of rails. The rails are configured to resist a portion of cantilever deflection along the length of the rails. The backpans seat solar concentrator arrays and are configured to provide torsional rigidity and deflection resistance in at least one direction orthogonal to the cantilever deflection.

### BRIEF DESCRIPTION OF DRAWINGS

FIG. 1 shows an isometric back view of an embodiment of a solar energy system;

FIG. 2 shows an isometric front view of the system of FIG. 1;

FIG. 3 depicts a perspective view of an exemplary backpan;

FIG. 4 is a cross-sectional view of exemplary solar concentrator units in the backpan of FIG. 3;

FIG. 5 provides an isometric view of the backpans of FIG. 3 mounted to an exemplary pair of rails;

FIG. 6 provides a close-up view of the assembly of FIG. 5;

FIG. 7 shows an end view of the assembly of FIG. 5;

FIG. 8 shows an exemplary bottom view of multi-panel assemblies mounted to a support beam; and

FIGS. 9A-9B depict full and close-up side views of an exemplary embodiment of the coupling between a panel assembly and a pedestal.

### DETAILED DESCRIPTION OF THE EMBODIMENTS

A solar panel assembly is disclosed in which rails are combined with one or more structurally rigid backpans to form a multi-panel assembly that requires minimal support when mounted to a tracking system. In typical solar energy installations, solar panels are designed as a piece of equipment to be mounted and aligned only, with the tracking system and auxiliary components being relied upon for the structural integrity of the overall installed solar assembly. By designing a solar panel assembly as a structural component as in the present invention, the amount of supporting framework that is required is simplified compared to conventional tracking systems. Consequently, costs associated with material and with installation of a solar energy system are reduced. Pedestal-type mounts, which conventionally require substantial support of the cantilever-type mounting of solar panels onto a central pedestal, can particularly benefit greatly from such a design. In addition, advantages related to maintaining and transporting the solar panel assemblies are realized.

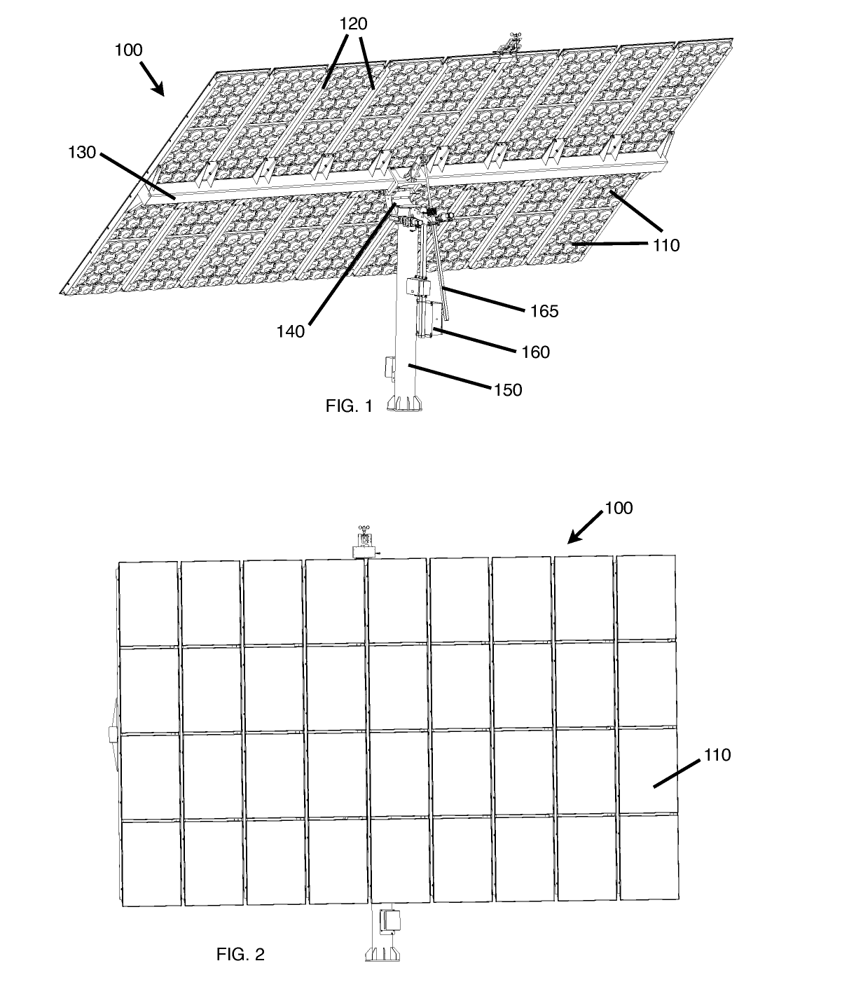

FIG. 1 shows a perspective back view of an embodiment of a solar assembly structure 100. The solar assembly structure 100 is shown as a pedestal-type design in this embodiment. The structure 100 includes solar panels 110 mounted to rails 120, rails 120 coupled to beam 130, beam 130 coupled to tracker head 140 and tracker head 140 coupled to pedestal 150. A column of panels 110 is mounted between two rails 120 to form a multi-panel assembly (MPA), and the multi-panel assemblies are placed side by side onto a solar tracker, which may include, for example, controllers 160 and actuators 165. The solar assembly structure 100 of FIG. 1 is shown in an intermediate position of tracking the sun during operation. That is, the panel assembly is oriented at angle to match the movement of the sun during the day, as determined by the tracking control system. FIG. 2 is a front view of the solar assembly 100 in a vertical position, representing, for example, early morning and late evening states of the tracking system.

In the embodiment of FIGS. 1 and 2, the solar assembly structure 100 includes thirty-six solar concentrator panels 110 arranged in a 4×9 array. In some embodiments, a single panel 110 may have a length or width on the order of, for example, 0.5 to 3 meters. However, the panel dimensions, array sizes and the number of panels for the system may be varied without departing from the scope of the invention. Although columns of arrays in these embodiments are shown on a horizontal support beam 130, it is also possible to invert the orientation to have rows of arrays mounted onto a “vertical” beam. Furthermore, the rails 120 and beam 130 need not necessarily be orthogonal, but may be oriented transversely at oblique angles to each other.

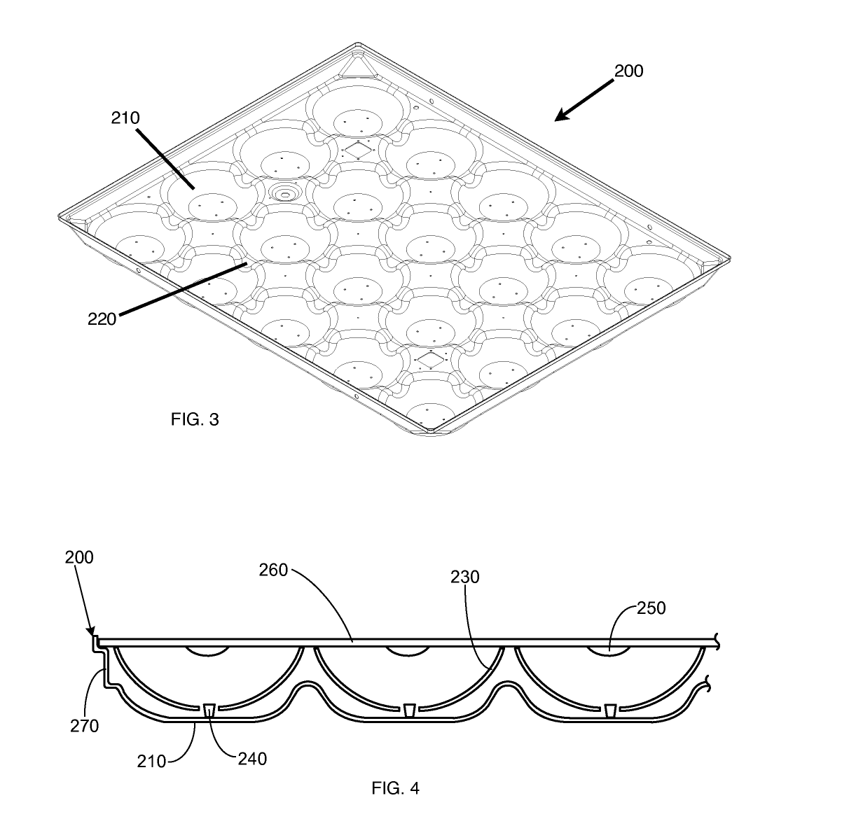

Each panel 110 includes a backpan in which individual concentrator units are seated. The assembly of solar concentrator units in one backpan may also be referred to as a solar concentrator array. FIG. 3 illustrates an exemplary backpan 200 that provides structural rigidity for a solar assembly structure of the present disclosure. The backpan 200 is specifically designed to be a rigid structure that is able to withstand, for instance, deflection due to the weight load of the array or due to wind and other environmental stresses (e.g., snow, rain, hail). Thus, the backpan 200 advantageously serves not only as a housing for solar concentrator components, but also as a structural component for installation of the array onto a tracking system. The rigidity of the backpan, combined with the rails on which the backpan is mounted, provides a structure that can sufficiently support a solar concentrator array with minimal additional components required to endure environmental stresses and maintain planar alignment of the arrays. In the case of a pedestal-mount design, which typically requires substantial framework to support the heavy cantilever loads of a large multi-panel array, the ability of the backpan to provide sufficient stiffness without additional beams or framework when mounted onto a tracker can provide significant reduction in material. This reduction of material translates into material cost savings, labor savings in manufacturing the tracking system, and weight reduction of the entire system. Furthermore, because the rails work in conjunction with the backpan to provide structural rigidity, the structural requirements for the rails may be reduced compared to conventional support rails, leading to additional cost savings.

In the embodiment of FIG. 3, backpan 200 includes depressions 210 connected by troughs 220. Depressions 210 and troughs 220 are shown as being integrally formed in the bottom surface of backpan 200. The depressions 210 seat solar concentrators, in which optical elements are used to concentrate light that is collected over a surface area onto a solar cell of a smaller area. The number of solar concentrator units seated in a backpan may be described as an “m×n” array. In the embodiment shown, the backpan 200 houses a 4×5 array of solar concentrator units. However, other array configurations for various numbers of solar concentrator units are possible. In some embodiments, “m” and “n” are both at least 2. Arrays of two or more rows or columns experience higher deflection and torsional stresses than a linear array, and thus may benefit more from the structural design of the present invention.

Troughs 220 of FIG. 3 augment the structural rigidity of backpan 200 and may also be used for routing electrical leads between the solar concentrator units that are located in each depression 210. The depressions 210 and connecting troughs 220 provide resistance to bending and torsional deflection of the pan under loads, in conjunction to the material selected for backpan 200. The backpan 200 may be fabricated from, for example, aluminum, steel, other sheet metals of non-ferrous alloys (for instance, brass or tin), composites, or a combination of these or other materials which can provide sufficient stiffness.

Various solar concentrators known in the art may be housed in the solar assembly structure of the present invention. Solar concentrators in the art may use, for example, one or more mirrors, Fresnel lenses, or other types of lenses to concentrate sunlight. Because solar concentrators typically incorporate more components—particularly glass mirrors and lenses—than flat solar panels, they often have a higher weight per area than flat panels and require more structural support. For instance, backpans of the present disclosure may house solar concentrators having a weight density of 15 kg per square meter or higher. The backpan of the present invention overcomes the need for a more complex and costly structural support assembly by providing structural rigidity in the backpan itself

In some embodiments of the present invention, the solar concentrators may have a Cassegrainian design. One example of a Cassegrainian system is depicted in FIG. 4, in which a primary mirror 230 and photovoltaic receiver 240 are seated in depressions 210, and a secondary mirror 250 is positioned and designed to reflect rays from the primary mirror 230 to be substantially focused at the entrance of the receiver 240. The secondary mirrors 250 may be mounted to a front panel 260, where the front panel 260 may be a transparent front window supported by side walls 270 of backpan 200. In one embodiment, the solar concentrator may be of the design disclosed in U.S. Pat. No. 8,063,300 entitled “Concentrator Solar Photovoltaic Array with Compact Tailored Imaging Power Units,” which is hereby incorporated by reference for all purposes.

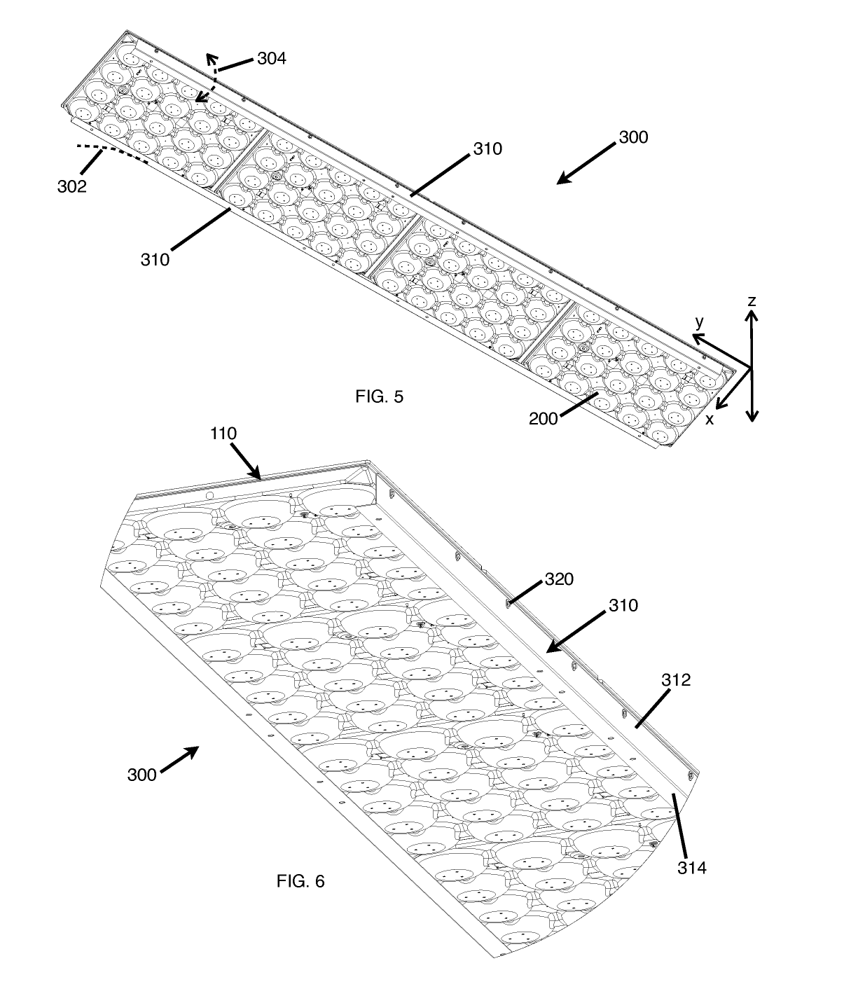

FIG. 5 shows a perspective bottom view of a multi-panel assembly (MPA) 300 in which the backpan 200 of FIG. 3 with solar concentrator units is mounted to an exemplary pair of rails 310. Note that while four panels are shown in the embodiment of FIG. 5, the multi-panel assembly 300 may comprise any number of backpans, including as few as one panel. FIG. 6 depicts a close-up bottom view of the assembly 300. In this embodiment the rails 310 have an L-shaped cross-section, consisting of a vertical face 312 joined at one edge to a horizontal face 314. The side walls of the backpans (e.g. side walls 270 of FIG. 6) are mounted to the vertical face 312 of the rails 310 with bolts 320, creating a quasi-bonded connection, and imparting a portion of the load from the rails to the backpan. In the embodiments of FIGS. 5 and 6, two bolts per backpan are used; however, any number of bolts may be used as desired. Furthermore, other fasteners such as clamps, rivets, tabs, and the like may be used instead of the bolts 320. In some embodiments, the mounting holes for bolts 320 may be positioned to maintain coplanar alignment of the panels when bolted to a tracker. That is, any sag due to the mass of the MPA structure may be precompensated for at the factory through specifically designed placement of the panel mounting holes.

In the MPA structure 300, the rails 310 resist at least a portion of the bending deflection along the length of the rails—e.g., bending in the z-direction as shown by dashed line 302—while the backpans 200 share the bending load and provide torsional rigidity and deflection resistance in the direction perpendicular to the rails—e.g., bending as shown by dashed line 304. That is, the rails are fixed rigidly to the backpan to share the required cantilever support for a column of solar panels (e.g., four panels in FIG. 5), without the need for additional supportive components underneath the backpan. Additionally, no frame or cross-beams are required to enclose the panels 110. Instead, the pair of rails 300 are coupled together only by the backpans 200. Materials for the rails 300 include, but are not limited to, aluminum, steel and composites such as carbon fiber or glass fiber reinforced plastics. Other embodiments of rail designs to resist bending deflection include, for example, I-beam, C-beam or even any other customized roll-formed shape to provide adequate mechanical properties in the locations they are needed. The specific material and thickness chosen for the rail should be designed according to the design loading cases and the environmental conditions to which the overall assembly will be subjected. Computer modeling may be utilized to optimize the design parameters—such as the backpan configuration, rail design, weight of the solar concentrators, material properties and material thicknesses—to achieve the desired strength and performance characteristics of the assembled structure under anticipated load conditions.

In some embodiments, the rail may be a steel rail of 0.5 mm to 2 mm thickness, with a vertical face 75 mm to 300 mm high and a horizontal face of 75 mm to 300 mm long. The backpan may be, for example, a 0.5 mm to 3 mm thick aluminum pan between 75 mm and 300 mm deep, and with multiple trough-like features with vertical dimensions between 12 mm and 75 mm.

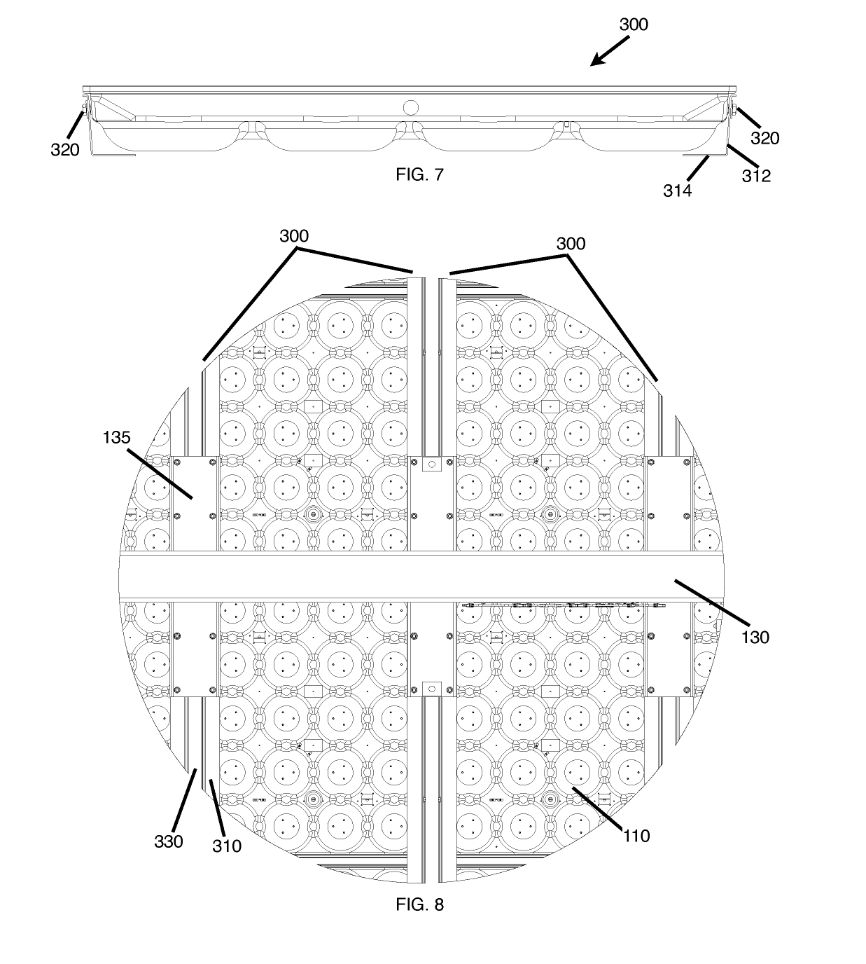

FIG. 7 depicts an end view of the MPA 300. The bolts 320 are inserted through holes in the backpan walls and in the rail. The structurally rigid backpans are coupled to the vertical face 312 of the rails, and do not require support from the bottom face 314 of the rail. In contrast, conventional systems often require the solar concentrators and their enclosures to be resting on a pan, tray, or framework spanning the underside of the multiple arrays to be mounted. The design of using a simplified rail design coupled to a rigid backpan greatly reduces the amount of steel and other material compared to conventional solar assembly structures, particularly for pedestal-mounted arrays. The rigidity and design of the structure is suitable for long-term operation of the concentrator, and enables modular replacement of individual panels during the lifetime of the assembly. Furthermore, the minimal hardware needed to mount the panels to the rails facilitates easy removal of a single solar concentrator panel for maintenance. This maintenance may take place in the field where the panels are installed for solar collection. In contrast, existing systems often require entire modules of multiple arrays to be removed together. The ability to remove individual panels in the present invention reduces the labor required for maintenance and reduces the downtime compared to removing an expansive module of many solar panels.

The backpan of the present invention, such as the backpan 200 embodied in FIG. 3, supports the weight of and provides stiffness to a solar concentrator array, while the rails to which the backpans are mounted assist in providing cantilever support to the multiple solar concentrator arrays. In other words, the backpan provides greater structural stiffness (e.g., torsional rigidity and deflection resistance) to the multi-panel assembly than is provided by the pair of rails (cantilever resistance) to which it is coupled. The backpan works symbiotically with its support structure. Both the backpan and the rails have very important structural roles in the overall solar assembly structure. The rails compensate for at least a portion of the bending moments along the MPA length, while the backpan handles the other two bending moments orthogonal to the rails, and also handles the torsional moment. The ability of displacing the torsional moment from the supporting frame to the backpan is a great advantage made possible by “sandwiching” the backpans in between two rails, creating a quasi-bonded connection. The front panel 260 and side walls 270 of FIG. 4 can also be designed to contribute to the structural stiffness of the solar assembly, while also serving to form an enclosure for the solar concentrator units. In one embodiment, the backpan may be of the design disclosed in U.S. Pat. No. 7,928,316, which is owned by the assignee of the present invention and entitled “Solar Concentrator Backpan,” which is hereby incorporated by reference for all purposes.

Further embodiments of backpans may include other features to create a rigid structure. For example, the backpan may include corrugations, indentations to hold the receivers, or honeycomb structures. In yet other embodiments, the backpan may be configured as a flat box enclosure having a material specifically selected to supply the necessary structural characteristics described above.

The multi-panel assembly 300 of FIGS. 5 and 6 is structurally rigid and therefore may be shipped as a modular unit. At the manufacturing site, in one example, individual power units may be mounted into the backpan to form a panel assembly housing a solar concentrator array, and then the individual panel assemblies are mounted to a pair of rails to form a multi-panel assembly. Transporting a multi-panel array, rather than shipping individual panel assemblies and then mounting them to a tracking system in the field, simplifies installation in the field and reduces labor costs because these costs are usually much higher at the installation location. In addition, mounting the panels to the rails at the manufacturing site advantageously enables the panels to be accurately aligned with each other prior to shipping, eliminating the need for this step in the field. This again saves time when installing the assemblies in the field. The high stiffness of the multi-panel assembly of the present invention enables the backpans to maintain proper alignment with the rails in during transport. Aligning the panels is particularly important for solar concentrators, since off-axis rays can impact the ability of solar radiation to be focused on the small photovoltaic cells that are typically used in solar concentrators. In some embodiments, for example, the multi-panel assemblies may be designed to maintain pre-determined alignment requirements. Thus, the efficiency of a fielded concentrator, and its installation speed, may be improved by enabling alignment of panels in the factory.

In FIG. 8, an exemplary bottom view of several multi-panel assemblies 300 mounted to a support beam 130 is shown. The support beam 130 of this embodiment is a torque tube. As can be seen in FIG. 8, only a single beam 130 is needed to support all of the multi-panel assemblies 300 since each MPA 300 is structurally rigid. The torque tube is designed to resist torsional deflection with respect to its longitudinal axis, and in this embodiment has flanges 135 extending slightly from the beam 130 to provide a mounting surface for the panel assemblies 300. The torque tube 130 may be a beam of rectangular cross-section as indicated in FIG. 8 or it could be, for example, a space frame or other lightweight, torsionally and flexurally rigid assembly or fabrication. The rails 310 of the multi-panel assemblies 300 are coupled to the flanges 135 via bolts, but may also be coupled by, for example, pins, clamps, or brackets. In the embodiment shown, a space 330 is maintained between adjacent rails 310, to facilitate removing specific multi-panel assemblies 300 or individual solar panels 110 for maintenance. The space 330 between adjacent rails 310 also allows for some degree of bending flexure in the torque tube 130, without the multi-panel assemblies 300 impacting each other. The space 330 also demonstrates the modular nature of the multi-panel assemblies 300.

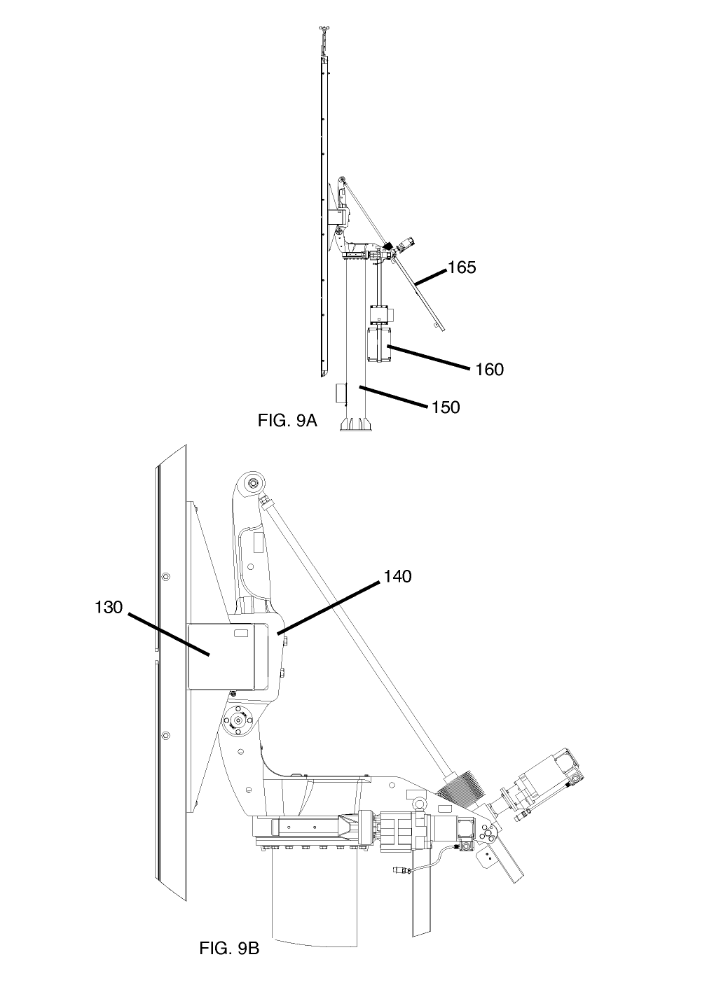

FIGS. 9A-9B depict full and close-up side views of an exemplary embodiment of the coupling between a panel assembly and a pedestal. In FIG. 9B, beam 130, which may also be referred to as a torque tube in this example, is coupled to tracker head 140. Tracker head 140 drives beam 130 and panel assemblies 110 into various positions during tracking (e.g., the positions shown in FIGS. 1-2), with the assistance of controllers 160 and actuator arms 165. In the exemplary embodiment shown in FIGS. 9A and 9B, the beam 130 and pedestal 150 are coupled together by a tracker head 140 that contains the electromechanical drives which provide dual-axes motion. The particular drives shown are a slew drive and a screw jack (which could also be an actuator). Other mechanisms are possible for achieving the necessary rotational and angular positioning of the tracking system, including but not limited to ball joints, universal joints and linear actuators. Furthermore, the multi-panel solar assembly of the present invention may be coupled to various tracker architectures other than the pedestal-type design as depicted.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention. Furthermore, those of ordinary skill in the art will appreciate that the foregoing description is by way of example only, and is not intended to limit the invention. Thus, it is intended that the present subject matter covers such modifications and variations.

What is claimed:

1. A solar concentrator assembly comprising:
a plurality of backpans, wherein each backpan is capable of seating a solar concentrator array; and
a plurality of rails, wherein a pair of rails in the plurality of rails is coupled together only by one or more backpans mounted between the pair of rails;
wherein the rails are configured to resist a portion of a cantilever deflection along the length of the rails, and wherein the backpan is configured to provide a) torsional rigidity and b) deflection resistance in at least one direction orthogonal to the cantilever deflection.

2. The assembly of claim 1 wherein each of the backpans is configured with a plurality of depressions and troughs integrally formed in a bottom surface of the backpan, and wherein the plurality of depressions are connected by the troughs.

3. The assembly of claim 2 wherein the plurality of troughs and depressions contribute to providing the torsional rigidity and the deflection resistance of the backpan, and wherein the plurality of troughs and depressions are capable of accommodating electrical leads.

4. The assembly of claim 1 further comprising a support beam upon which the rails are mounted, wherein the rails are mounted transverse to the support beam.

5. The assembly of claim 4 further comprising a tracker head and a pedestal, wherein the support beam is coupled to the tracker head and to the pedestal.

6. The assembly of claim 1 wherein each pair of rails and the one or more backpans mounted in the pair of rails defines a multi-panel assembly, and wherein the multi-panel assemblies are modular from each other.

7. The assembly of claim 6 wherein the one or more backpans provides greater structural stiffness to the multi-panel assembly than is provided by the plurality of rails.

8. The assembly of claim 1 wherein the backpan resists a portion of a cantilever deflection along the length of the rails.

9. The assembly of claim 1 wherein the backpan is fabricated from aluminum having a thickness between 0.5-3.0 mm.

10. The assembly of claim 1 wherein each rail consists of a vertical face and a horizontal face forming an L-shaped cross-section, and wherein the backpan is mounted to the vertical face of the rail.

11. The assembly of claim 10 wherein the rail is fabricated from steel having a thickness between 0.5-2.0 mm, wherein the vertical face is 75-300 mm high, and wherein the horizontal face is 75-300 mm long.

12. The assembly of claim 1, wherein the backpans are pre-aligned with the rails at a manufacturing location, and wherein the rails maintain the pre-alignment throughout transport to a field location and assembly in the field location.

13. The assembly of claim 1, wherein the solar concentrator array is an array of m×n solar concentrators, wherein m equals at least 2 and n equals at least 2.

14. A method of manufacturing a solar concentrator panel assembly, the method comprising the steps of:
seating a solar concentrator array in a backpan;
providing a pair of rails, wherein the rails are configured to resist a portion of a cantilever deflection; and
mounting one or more backpans between the pair of rails, wherein the rails are coupled together by only the one or more backpans, and wherein the one or more backpans mounted to the rails comprises a multi-panel assembly;
wherein each backpan is configured to provide a) torsional rigidity and b) deflection resistance in a direction transverse to the rails; and
wherein the multi-panel assembly is capable of maintaining a pre-determined alignment between the backpans and the rails while being transported.

15. The method of claim 14, further comprising the step of aligning the backpans in the rails prior to being transported.

16. The method of claim 14, further comprising the steps of:
coupling the panel assembly to a torque tube;
coupling the torque tube to a tracker head; and
coupling the tracker head to a pedestal mount.
